(19) United States
(12) Patent Application Publication
(10) Pub. No.: US 2026/0239607 A1
(43) Pub. Date: Aug. 13, 2026

(54) MICROELECTRONIC DEVICES INCLUDING BACK GATE STRUCTURES AND BACK GATE PLATES, AND RELATED MEMORY DEVICES AND ELECTRONIC SYSTEMS

(71) Applicant: Micron Technology, Inc., Boise, ID (US)

(72) Inventors: Marcello Mariani, Milano (IT); Giorgio Servalli, Fara Gera D'Adda (IT); Kamal M. Karda, Boise, ID (US); Eijii Hasunuma, Hiroshima (JP)

(21) Appl. No.: 19/450,621

(22) Filed: Jan. 15, 2026

Related U.S. Application Data
(60) Provisional application No. 63/758,265, filed on Feb. 13, 2025.

(51) Int. Cl. H10B 12/00

(52) U.S. Cl. CPC H10B 12/482; H10B 12/05; H10B 12/315; H10B 12/488

(57) ABSTRACT

A microelectronic device includes a memory array structure including an array region having vertical channel access devices of memory cells within a horizontal area thereof, the vertical channel access devices having word line structures extending in a first horizontal direction and back gate structures horizontally interposed between neighboring vertical channel access devices in a second horizontal direction, orthogonal to the first horizontal direction, and extending in the first horizontal direction. The microelectronic device further includes an edge of array region horizontally neighboring the memory array structure in the first horizontal direction, digit line structures vertically overlying the vertical channel access devices of the memory cells, a shield structure vertically overlying the digit line structures of the memory cells of the memory array structure, and a back gate plate formed within the edge of array region, in contact with the back gate structures of the memory array structure, and at least partially vertically overlapping with the digit line structures.

### CROSS-REFERENCE TO RELATED APPLICATIONS

This application claims the benefit under 35 U.S.C. § 119(e) of U.S. Provisional Patent Application Ser. No. 63/758,265, filed Feb. 13, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device. Furthermore, as the density and complexity of the memory array have increased, so has the complexity of the control logic devices. In some instances, the control logic devices consume more real estate than the memory devices, reducing the memory density of the memory device. Moreover, capacitors for regulating and supplying voltages to the control logic devices can require substantial footprints.

### BRIEF DESCRIPTION OF THE DRAWINGS

For a detailed understanding of the disclosure, reference should be made to the following detailed description, taken in conjunction with the accompanying drawings, in which like elements have generally been designated with like numerals, and wherein:

FIG. 1 through FIG. 9 include simplified, perspective views of a microelectronic device structure at different processing stages of a method of forming a microelectronic device, according to one or more embodiments of the disclosure;

FIG. 10 shows a simplified, vertical cross-sectional view of a microelectronic device at a processing stage of the method of forming a microelectronic device following the processing stage of FIG. 9, according to one or more embodiments of the disclosure;

FIG. 11 shows a schematic top view of a microelectronic device at a processing stage of a method of forming a microelectronic device, according to one or more embodiments of the disclosure; and

FIG. 12 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials. As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, the term “sacrificial material” means and includes a material that is formed and/or employed during a fabrication process but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

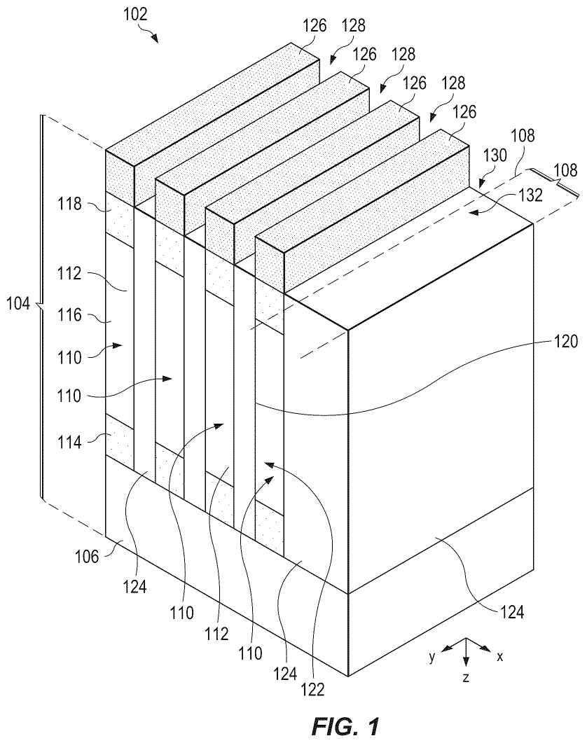

FIG. 1 through FIG. 9 include simplified, perspective views of a memory array structure 102 at different processing stages of a method of forming a microelectronic device (e.g., a memory device, such as Dynamic Random Access Memory (DRAM) device, a Hierarchical Random Access Memory (HRAM) device, a Ferroelectric Random Access Memory (FeRAM) device, a Synchronous Dynamic Random Access Memory (SDRAM) device, a Magnetoresisive Random Access Memory (MRAM) device), in accordance with embodiments of the disclosure. With the description provided below, it will be readily apparent to one of ordinary skill in the art that the methods described herein may be used for forming various devices.

Referring to FIG. 1, forming the memory array structure 102 may include forming a first assembly 104. The first assembly 104 may also be referred to herein as a die or a wafer. The first assembly 104 may at least include a semiconductor structure (e.g., a semiconductor wafer), or a base semiconductive material on a support structure or construction upon which additional materials and structures of the memory array structure 102 are formed. For example, the first assembly 104 may include a first carrier structure 106 including one or more of a semiconductor (e.g., silicon) substrate and an insulative structure.

The memory array structure 102 may be formed adjacent to an edge of array region 108 of the microelectronic device in the X-direction. Put another way, the memory array structure 102 may horizontally neighbor the edge of array region 108 of the microelectronic device (e.g., edge of die) in the X-direction. In particular, the edge of array region 108 may be defined at horizontal edges of neighboring patch regions or bank regions of the microelectronic device.

The memory array structure 102 may include semiconductor projections 110 extending from an upper surface of the first carrier structure 106 and formed on or over the first carrier structure 106. The semiconductor projections 110 may include a semiconductor material; and, together with the first carrier structure 106, may form a silicon-over-insulator (SOI) substrate. The semiconductor projections 110 may be laterally spaced apart by trenches 112 extending vertically into the first assembly 104 and between neighboring semiconductor projections 110 of the memory array structure 102. The trenches 112 may extend horizontally in parallel in the Y-direction (e.g., a first direction) and may be referred to herein as “y-axis trenches 112.” The y-axis trenches 112 may have any suitable dimensions. In some embodiments, the y-axis trenches 112 have vertical depths (e.g., vertical heights) within a range of from about 100 nm to about 200 nm (e.g., about 145 nm).

The semiconductor projections 110 may include silicon structures, such as an epitaxial silicon structures. Additionally, each of the semiconductor projections 110 may include a first doped region 114 vertically overlying the first carrier structure 106, an undoped region 116 vertically overlying the first doped region 114, and a second doped region 118 vertically overlying the undoped region 116. In some embodiments, each of the first doped region 114 and the second doped region 118 are n-type doped, such as N-type doped to an N-type dopant concentration within a range of from about 10¹⁵ cm⁻³ to about 10²⁰ cm⁻³. In additional embodiments, one of the first doped region 114 and the second doped region 118 is N-type doped while the other of the first doped region 114 and the second doped region 118 may be P-type doped, such as P-type doped to a P-type dopant concentration within a range of from about −10¹³ cm⁻³ to about −10¹⁸ cm⁻³. In additional embodiments, one or more of the first doped region 114 and the second doped region 118 is doped (either P-doped or N-doped) to the point of saturation (e.g., greater than or equal to about −10¹⁸ cm−³). The doping may be accomplished utilizing any suitable processing, such as by implanting dopant (e.g., at least one N-type dopant or at least one P-type dopant) into the semiconductor projections 110 or a structure formed into the semiconductor projections 110. A P-type dopant may include one or more of boron, aluminum, and gallium; and an N-type dopant may include one or more of arsenic, phosphorous, antimony, and bismuth.

In some embodiments, the undoped region 116 does not include any P-type dopants or any N-type dopants. In alternative embodiments, the undoped region 116 is doped with one of the dopants described herein and become another doped region.

In one or more embodiments, the first doped region 114 forms a drain region of a later-formed vertical channel access device (VCAD) (e.g., vertical channel transistor (VCT)), the undoped region 116 forms a channel region of the later-formed VCAD, and the second doped region 118 forms a source region of the later-formed VCAD.

The memory array structure 102 may include a separation trench 120 formed within the edge of array region 108 and spanning an interface of the memory array structure 102 with edge of array region 108. For example, a vertical side surface of a semiconductor projection 110 of the memory array structure 102 most proximate the edge of array region 108 in the X-direction may define a first horizontal boundary of the separation trench 120 in the X-direction. The semiconductor projection 110 most proximate the edge of array region 108 in the X-direction may be referred to herein as an “outermost semiconductor projection 122.”

In some embodiments, a second horizontal boundary of the separation trench 120 in the X-direction is defined by a semiconductor projection of another memory array structure on an opposite side of the edge of array region 108. For example, the memory array structure 102 and the another memory array structure may be formed on opposing sides of the edge of array region 108 of the microelectronic device in the X-direction. Put another way, each of the memory array structure 102 and the another memory array structure may horizontally neighbor and flank the edge of array region 108 of the microelectronic device (e.g., edge of die) in the X-direction.

In additional embodiments, the separation trench 120 does not have a defined second horizontal boundary in the X-direction. For example, the separation trench 120 may be open to a horizontal lateral side of the microelectronic device. In particular, the separation trench 120 may form a so called “cutout” that is accessible from an upper surface of the memory array structure 102 and an adjacent lateral side surface of the memory array structure 102.

A first isolation material 124 may be formed within the y-axis trenches 112 and within the separation trench 120 within the edge of array region 108 of the microelectronic device. For instance, the y-axis trenches 112 and the separation trench 120 may be filled with the first isolation material 124. In some embodiments, the first isolation material 124 is formed of and includes a dielectric oxide material, such as SiOₓ (e.g., SiO₂). The first isolation material 124 may be substantially homogeneous, or the first isolation material 124 may be heterogeneous. The first isolation material 124 may, for example, be formed of and include a stack of at least two different dielectric materials. The first isolation material 124 may be formed (e.g., deposited) via and of the manners described herein.

In some embodiments, the first assembly 104 further includes a first dielectric liner material formed in the y-axis trenches 112, over the semiconductor projections 110 of the memory array structure 102, and between the semiconductor projections 110 and the first isolation material 124. The first dielectric liner material may be formed over and alongside surfaces of the semiconductor projections 110 and upper surfaces of the first carrier structure 106 between neighboring semiconductor projections 110.

In one or more embodiments, the first dielectric liner material is also formed within the separation trench 120. Within the separation trench 120, the first dielectric liner material may be formed over an upper surface of first carrier structure 106 extending from the outermost semiconductor projection 122 in the X-direction and into the edge of array region 107 of the microelectronic device. The first dielectric liner material may be formed of and include insulative material. In some embodiments, the first dielectric liner material is formed of and includes silicon dioxide.

Referring still to FIG. 1, digit line structures 126 (e.g., bit line structures, data line structures) may be formed on or over the semiconductor projections 110 of the memory array structure 102 of the first assembly 104. In particular, the digit line structures 126 are formed vertically on or over each of the semiconductor projections 110 of the memory array structure 102 of the first assembly 104. The digit line structures 126 may be formed of and include a conductive material. The conductive material may include one or more conductive materials. In some embodiments, the conductive material includes tungsten, either alone or in combination with one or more conductive barrier materials (e.g., oxidation resistant materials which protect the tungsten from oxidation in embodiments in which the tungsten may be exposed to oxygen).

The digit line structures 126 may be formed to any suitable dimensions (e.g., width, thickness). By way of example, the digit line structures 126 may individually be formed to a width, in the X-direction, equal to about the width of an individual semiconductor projections 110 (e.g., in a range of from about 10 nm to about 30 nm). The digit line structures 126 may be formed to any suitable pitch. The digit line structures 126 may be spaced apart from one another by a distance equal to about the distance between the semiconductor projections 110 horizontally neighboring one another in the X-direction.

The digit line structures 126 may be formed using any suitable processing. For instance, the conductive material may be formed on or over the upper surface of the first assembly 104 (e.g., upper surfaces of the first isolation material 124 and the first doped regions 114 of the semiconductor projections 110), and a first mask material may be formed over an upper surface of the conductive material, and the first mask material may be patterned to form patterned masking lines horizontally extending in parallel with one another in the Y-direction. The first mask material may be patterned into the patterned masking lines utilizing any suitable methodology. For instance, in some embodiments, a photoresist material is formed on or over the first mask material, is patterned (e.g., photo exposed and developed), and then Openings formed in the patterned photoresist material are extended into the first mask material to form the patterned masking lines.

The patterned masking lines may be employed to form additional y-axis trenches 128 extending vertically through the conductive material formed over the memory array structure 102. The additional y-axis trenches 128 may extend horizontally in parallel in the Y-direction. The additional y-axis trenches 128 may have any suitable dimensions. For instance, the additional y-axis trenches 128 may have a width, in the X-direction, at least substantially equal to about the width of an individual space between neighboring semiconductor projections. In some embodiments, the additional y-axis trenches 128 are formed using an etching process (e.g., an anisotropic etching process) that selectively removes exposed portions of the conductive material relative to the patterned masking lines without removing portions of the first isolation material 124. Accordingly, lower boundaries (e.g., bottoms) of the additional y-axis trenches 128, as defined by upper surfaces of the first isolation material 124, may be substantially planar.

Referring still to FIG. 1, the first mask material may also be utilized to form a second separation trench 130 extending vertically through the conductive material or any other materials over the first isolation material 124 within the edge of array region 108 and the first isolation material 124 between the edge of array region 108 and the outermost semiconductor projection 122. Formation of the second separation trench 130 may expose an upper surface 132 of the first isolation material 124 within the edge of array region 108 and the first isolation material 124 between the edge of array region 108 and the outermost semiconductor projection 122.

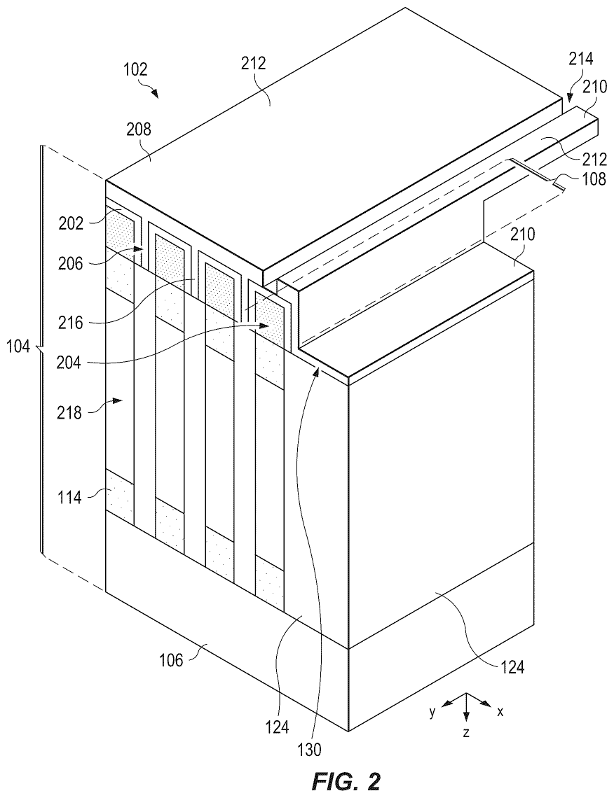

Referring to FIG. 2, a second dielectric liner material 202 may be formed within the additional y-axis trenches 128, over the digit line structures 126 and the first isolation material 124 of the memory array structure 102; within the second separation trench 130, over the first isolation material 124 within the edge of array region 108; and over the first isolation material 124 between the edge of array region 108 and the outermost semiconductor projection 122. For instance, the second dielectric liner material 202 may be formed (e.g., conformally deposited) inside the additional y-axis trenches 128, over the digit line structures 126, inside the second separation trench 130, over the first isolation material within the edge of array region 108, and over the first isolation material 124 between the edge of array region 108 and the second dielectric liner material 202 lining a digit line structure 126 most proximate the edge of array region 108 in the X-direction. The digit line structure 126 most proximate the edge of array region 108 in the X-direction may be referred to herein as an “outermost digit line structure 204.” In some embodiments, the second dielectric liner material 202 does not entirely fill the additional y-axis trenches 128 or the second separation trench 130. For instance, recesses 206 may remain between portions the second dielectric liner material 202 deposited on the vertical sidewalls of the digit line structures 126 of the memory array structure 102.

Within the additional y-axis trenches 128, the second dielectric liner material 202 may include side portions on the side surfaces of the digit line structures 126, and, optionally, bottom portions on or over the upper surfaces of the first isolation material 124. In some embodiments, portions of the bottom portions of the second dielectric liner material 202 lining the upper surfaces of the first isolation material 124 are removed by way of one or more of any of the removal processes described herein.

The second dielectric liner material 202 may be formed of and include insulative material. In some embodiments, the second dielectric liner material 202 is formed of and includes silicon dioxide. The second dielectric liner material 202 may have a thickness within a range of from about 3 nm to about 7 nm (e.g., about 5 nm).

Referring still to FIG. 2, a shield structure 208 and a back gate plate 210 may be formed over the second dielectric liner material 202 and an exposed surfaces of the first isolation material 124. For instance, a conductive material 212 may be deposited (e.g., conformally deposited) within the recesses 206, over the second dielectric liner material 202, over upper surfaces of the first isolation material 124 between neighboring digit line structures 126, over an upper surface of the first isolation material within the edge of array region 108, and over an upper surface of the first isolation material 124 between the edge of array region 108 and the outermost digit line structure 204. In particular, the conductive material 212 may be deposited over any exposed upper surface of the first isolation material 124 within the second separation trench 130.

The conductive material 212 may be patterned to form the shield structure 208 and the back gate plate 210. In particular, a dividing slot 214 may be formed within the conductive material 212 to separate the shield structure 208 from the back gate plate 210. The dividing slot 214 may be formed to extend vertically through the conductive material 212 and to the second dielectric liner material 202 over the outermost digit line structure 204. The dividing slot 214 may extend horizontally in the Y-direction. The dividing slot 214 may be formed to at least partially horizontally overlap and be directly vertically above the outermost digit line structure 204. In particular, a cross-sectional area of the dividing slot 214 defined by horizontal boundaries of the dividing slot 214 within an XY plane may at least partially horizontally overlap with a cross-sectional area of the outermost digit line structure 204 with an XY plane. In some embodiments, at least one horizontal boundary of the dividing slot 214 defined within a ZY plane is formed horizontally in-between parallel horizontal boundaries of the outermost digit line structure 204 within ZY planes. Put another way, at least one horizontal boundary of the dividing slot 214 may be in-between, in the X-direction, the horizontal boundaries of the outermost digit line structure 204. In one or more embodiments, at least one horizontal boundary of the dividing slot 214 defined within a ZY plane is formed directly vertically above a horizontal boundary of the outermost digit line structure 204 within the ZY plane. In other words, a surface defining at least one horizontal boundary of the dividing slot 214 may be coplanar with a surface defining a horizontal boundary of the outermost digit line structure 204 within the ZY plane.

Referring still to FIG. 2, a portion of the conductive material 212 vertically overlying the digit line structures 126 other than the outermost digit line structure 204 may form the shield structure 208. In addition, another portion of the conductive material 212 vertically overlying the outermost digit line structure 204, lining the second dielectric liner material 202 lining a vertical side surface of the outermost digit line structure 204 most proximate the edge of array region 108, and vertically overlying the upper surface of the first isolation material 124 within the edge of array region 108 and the upper surface of the first isolation material 124 between the edge of array region 108 and the second dielectric liner material 202 lining the outermost digit line structure 204 may form the back gate plate 210. However, while not referred to as a shield structure herein, the back gate plate 210 may provide the one or more of the shielding properties described herein.

The shield structure 208 may at least substantially entirely fill the recesses 206 and cover upper surfaces of the first isolation material 124 extending between horizontally neighboring digit line structures 126. As a result, in some embodiments, the shield structure 208 includes projections 216 extending vertically downward between horizontally neighboring digit line structures 126. Moreover, because the shield structure 208 at least substantially entirely fills the recesses 206, the shield structure 208 may extend vertically in-between neighboring digit line structures 126. Put another way, portions of the shield structure 208 may be horizontally interposed between neighboring digit line structures 126 of the memory array structure 102.

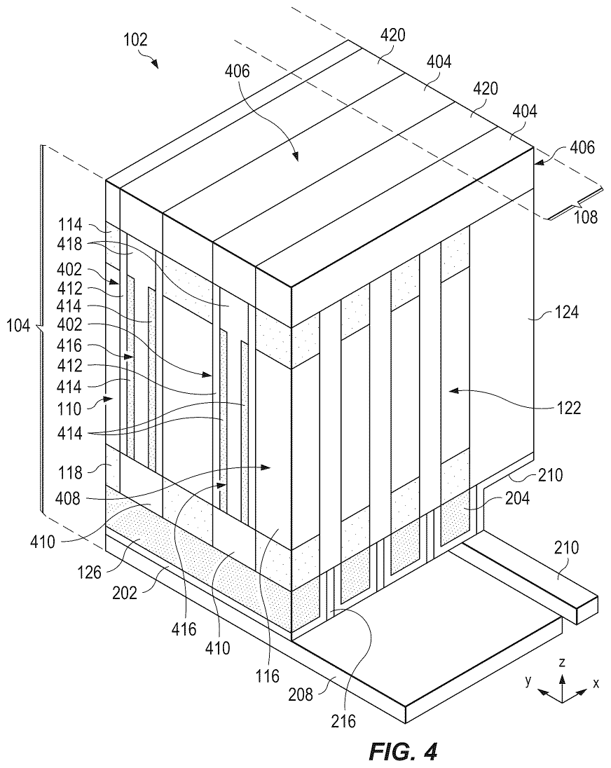

The shield structure 208 (e.g., upper shielding plate, top shielding plate) may be configured and positioned to shield (e.g., protect) features (e.g., structures, materials, devices, digit lines) within portions of memory cells (e.g., vertical channel access devices 218 (FIG. 4) (described below)) of the memory array structure 102 from undesirable electrical interference (e.g., electromagnetic interference (EMI)).

In some embodiments, the second dielectric liner material 202 at least substantially fills the additional y-axis trenches 128, and the shield structure 208 is formed over a substantially uniform or continuous upper surface of the second dielectric liner material 202. As a result, in some embodiments, the shield structure 208 does not include the projections 216 extending vertically downward between horizontally neighboring digit line structures 126 and, rather, may include a generally flat structure.

In view of the foregoing, the shield structure 208 may vertically overlie the digit line structures 126, of the memory array structure 102. Accordingly, vertical channel access devices (to be subsequently formed) of the memory array structure 102 may be vertically interposed between the digit line structures 126 and an associated multi-storage node structure that may be attached to the memory array structure 102 to form a second assembly in later processes.

The multi-storage node structure may include multiple storage node devices (e.g., capacitors) formed on or over a redistribution layer (RDL) tier and formed redistribution material (RDM) structures. The second assembly may include the first assembly 104 and the multi-storage node structure. The storage node devices may be in electrical contact with the RDM structures, and, hence, with contact structures of the semiconductor projections 110 (e.g., and, hence, vertical channel access devices 218 (FIG. 4)) of the first assembly 104. The storage node devices may be coupled to the semiconductor projections 110 by way of the contact structures and the RDM structures to form memory cells (e.g., DRAM cells).

Each memory cell may individually include one of the vertical channel access devices, one of the storage node devices, one of the contact structures, and one of the RDM structures. The storage node devices may individually be formed and configured to store a charge representative of a programmable logic state of the memory cell including the storage node device.

In some embodiments, the storage node devices include capacitors. During use and operation, a charged capacitor may represent a first logic state, such as a logic 1; and an uncharged capacitor may represent a second logic state, such as a logic 0. Each of the storage node devices may, for example, be formed to include a first electrode (e.g., a bottom electrode), a second electrode (e.g., a top electrode), and a first dielectric material between the first electrode and the second electrode. For instance, each of the storage node devices may include a metal-insulator-metal (MIM) capacitor. As another example, each of the storage node devices may include a metal-insulator-semiconductor (MIS) capacitor. The collection of memory cells may form a memory array of the memory array structure 102 and microelectronic device.

As mentioned briefly above, the back gate plate 210 may vertically overlie at least a portion the outermost digit line structure 204, line the second dielectric liner material 202 lining a vertical side surface of the outermost digit line structure 204 most proximate the edge of array region 108, and vertically overlie the upper surface of the first isolation material 124 within the edge of array region 108 and the upper surface of the first isolation material 124 between the edge of array region 108 and the second dielectric liner material 202 lining the outermost digit line structure 204. Put another way, the back gate plate 210 may line surfaces of structures defining the second separation trench 130. Furthermore, as depicted in FIG. 2, a lowermost surface of the back gate plate 210 may be at least substantially coplanar with lowermost surfaces of the digit line structures 126. Moreover, the back gate plate 210 may vertically overlap with the digit line structures 126.

As noted above, the shield structure 208 and the back gate plate 210 may be formed of and include conductive material. In some embodiments, the shield structure 208 and the back gate plate 210 are formed of and includes metallic material, such as one or more of at least one metal, at least one alloy, and at least one conductive metal-containing material (e.g., a conductive metal nitride, a conductive metal silicide, a conductive metal carbide, a conductive metal oxide). By way of non-limiting example, the shield structure 208 and the back gate plate 210 may be formed of and include tungsten (W). The shield structure 208 and the back gate plate 210 may be substantially homogeneous, or the shield structure 208 and the back gate plate 210 may be heterogeneous. If the shield structure 208 and the back gate plate 210 are heterogeneous, amounts of one or more elements included in the shield structure 208 and the back gate plate 210 may vary stepwise (e.g., change abruptly), or may vary continuously (e.g., change progressively, such as linearly, parabolically) throughout different portions of the shield structure 208 and the back gate plate 210. The shield structure 208 and the back gate plate 210 may, respectively, for example, be formed of and include a stack of at least two different conductive materials.

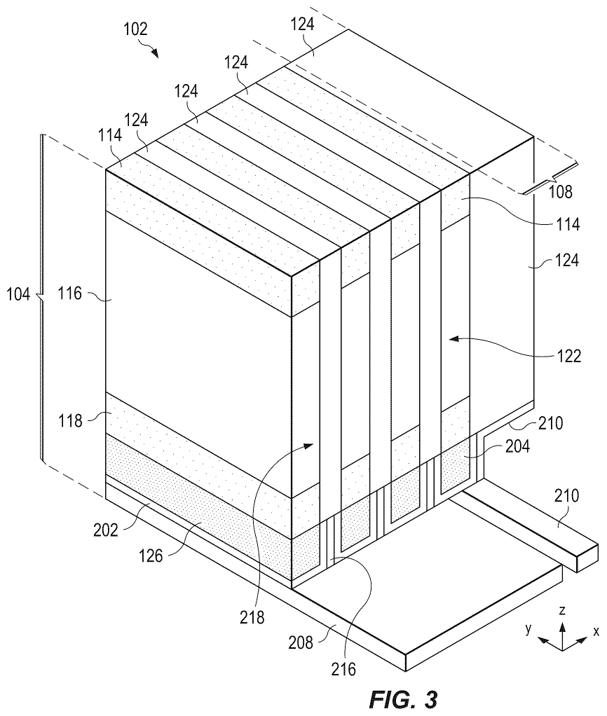

Referring now to FIG. 3, the first assembly 104 may be vertically inverted such that the semiconductor projections 110 vertically overlie the shield structure 208 and the back gate plate 210, and then at least one thinning process (e.g., a CMP process; an etching process, such as a conventional dry etching process or a wet etching process) may be performed on the first carrier structure 106 of the first assembly 104 to remove the first carrier structure 106. Furthermore, the thinning process may be stopped at upper surfaces (following vertical inversion) of the first isolation material 124 and the first doped regions 114 of the semiconductor projections 110. For instance, the thinning process (e.g., the removal process) may be stopped at a vertical elevation at least substantially coplanar with an upper vertical boundary, as depicted in FIG. 3, of the semiconductor projections 110. In some embodiments, the first assembly 104 is bonded to a second carrier structure prior to being vertically inverted. For example, the second carrier structure may be bonded to upper surfaces the shield structure 208 and back gate plate 210 prior to inversion, and the second carrier structure may be utilized to facilitate inversion.

Referring to FIG. 4, additional trenches 402 may be formed to extend vertically into the first assembly 104. In particular, the additional trenches 402 may be formed to extend vertically into the semiconductor projections 110 of the memory array structure 102. The additional trenches 402 may extend horizontally in parallel in the X-direction (e.g., a second direction) perpendicular to the Y-direction and may be referred to herein as “first x-axis trenches 402.”

In some embodiments, the first x-axis trenches 402 are formed using a second mask material 404 and an etching process (e.g., an anisotropic etching process) that removes exposed portions of the first isolation material 124 and the semiconductor projections 110. For example, the second mask material 404 may be formed over upper surfaces of the first isolation material 124 and the first doped regions 114 of the semiconductor projections 110, and the second mask material 404 may be patterned to form second patterned masking lines 406 horizontally extending in parallel with one another in the X-direction. The second mask material 404 may be patterned into the second patterned masking lines 406 utilizing any suitable methodology. For instance, in some embodiments, a photoresist material is formed on or over the second mask material 404, is patterned (e.g., photo exposed and developed), and then openings formed in the patterned photoresist material are extended into the second mask material 404 to form the second patterned masking lines 406. The second mask material 404 may be formed of and include a dielectric material, such as a dielectric nitride material (e.g., silicide nitride).

The second patterned masking lines 406 may be employed to form the first x-axis trenches 402. The first x-axis trenches 402 may be formed to terminate (e.g., have lower boundaries) at upper vertical boundaries of the digit line structures 126, the projections 216, the second dielectric liner material 202, and the back gate plate 210. Accordingly, lower boundaries (e.g., bottoms) of the first x-axis trenches 402 may be defined by upper surfaces, as depicted in FIG. 4, of the digit line structures 126, the projections 216, the second dielectric liner material 202, and the back gate plate 210. As a result, semiconductor pillars 408 may be formed from the semiconductor projections 110, and the semiconductor pillars 408 may be distinct and discrete from each other.

The first x-axis trenches 402 may be partially filled within a spacer material 410. In one or more embodiments, the spacer material 410 is deposited within the first x-axis trenches 402 through a spin-on coating process. For instance, the spacer material 410 may include a spin-on dielectric. Furthermore, subsequent to the spin-on coating process, the spacer material 410 may be recessed (e.g., removed through an etching process (dry or wet etching process)) to leave only portions of the spacer material 410 at the bottoms of the first x-axis trenches 402.

In some embodiments, the spacer material 410 is formed of and includes a dielectric oxide material, such as SiOₓ (e.g., SiO₂). The spacer material 410 may be substantially homogeneous, or the spacer material 410 may be heterogeneous. The spacer material 410 may, for example, be formed of and include a stack of at least two different dielectric materials.

The degree to which the spacer material 410 is recessed may serve to position the later-formed gate electrodes (i.e., word lines) a desired distance from the digit line structures 126, the shield structure 208, and a boundary of the second doped region 118 and the undoped region 116 of the semiconductor projections 110. For instance, the remaining portion of the spacer material 410 may space the later-formed gate electrodes (i.e., word line structures (described below)) from the digit line structures 126, the shield structure 208, and a boundary of the second doped region 118 and the undoped region 116 of the semiconductor projections 110 by desired distances, and as a result, may space the later-formed gate electrodes (i.e., word line structures) from the digit line structures 126. For example, the thickness of the spacer material 410 may at least partially determine a distance between the later-formed gate electrodes (i.e., word line structures) and a digit line junction. The remaining portion of the spacer material 410 may exhibit a thickness within a range of from about 30 nm to about 60 nm. For instance, the spacer material 410 may be etched to have a thickness of about 45 nm.

A third dielectric liner material 412 (i.e., a gate dielectric material) may be formed in the first x-axis trenches 402, over the semiconductor projections 110 (i.e., pillars), and over the spacer material 410 of the memory array structure 102. The third dielectric liner material 412 may also be referred to as a gate dielectric material. The third dielectric liner material 412 is formed over and along vertical side surfaces of the semiconductor projections 110 (i.e., semiconductor pillars) and upper surfaces of the spacer material 410. In some embodiments, bottom portions of the third dielectric liner material 412 are removed by way one or more removal processes such that upper surfaces of the spacer material 410 are exposed.

The third dielectric liner material 412 (i.e., gate dielectric material) may be formed of and include insulative material. In some embodiments, the third dielectric liner material 412 is formed of and includes silicon dioxide. In one or more embodiments, the third dielectric liner material 412 includes a material with a relatively high dielectric constant (k) (i.e., a high-k material). In some embodiments, the third dielectric liner material 412 is formed (e.g., conformally deposited) inside and outside of the first x-axis trenches 402. The third dielectric liner material 412 may have a thickness within a range of from about 4 nm to about 6 nm (e.g., about 5 nm).

Word line structures 414 (e.g., access lines, gate electrodes, gate metal) may be formed on the second dielectric liner material 202 and within the first x-axis trenches 402. The word line structures 414 may include any of the conductive materials described herein.

In one or more embodiments, the word line structures 414 are formed by at least partially filling the first x-axis trenches 402 with a gate electrode material, and subsequently removing one or more portions of the gate electrode material. As non-limiting examples, within the first x-axis trenches 402, subsequent to depositing the gate electrode material within the first x-axis trenches 402, an entirety of the gate electrode material may be recessed down to a desired upper boundary of the word line structures 414, and a center portion of the gate electrode material may be further recessed (e.g., removed) to form recesses 416 extending vertically through the remaining gate electrode material and to the spacer material 410. As a result, two word line structures 414 separated by a respective recess 416 may be formed within each of the first x-axis trenches 402.

The gate electrode material may be formed (e.g., deposited) through any of the manners described herein. Additionally, recessing the gate electrode material and forming the recesses in the gate electrode material may be done by conventional techniques, such as by a directional, selective etch process (e.g., an anisotropic etch process, such as an anisotropic dry or wet etch process) that removes the gate electrode material without significantly removing other exposed materials (e.g., the third dielectric liner material 412 and the spacer material 410) of the first assembly 104.

The recesses 416 may be formed to a desired width (e.g., horizonal dimension) in the Y-direction such that portions of the gate electrode material (i.e., the word line structures 414) remain adjacent to the third dielectric liner material 412 in the Y-direction. In other words, the width of the recesses 416 may be selected to result in a desired width of the word line structures 414 (i.e., gate electrodes) formed from the gate electrode material in the Y-direction.

The semiconductor projections 110 (including the first doped regions 114, the undoped regions 116, and the second doped regions 118 thereof), the third dielectric liner material 412, and the word line structures 414 may together form vertical channel access devices 218. As individual vertical channel access device 218 may include a channel region comprising the undoped region 116 of an individual semiconductor projection 110, a drain region comprising the first doped region 114 of the semiconductor projection 110, and a source region comprising the second doped region 118 of the semiconductor projection 110. In addition, the vertical channel access device 218 may include a gate electrode comprising a portion of an individual word line structure 414, and a gate dielectric material comprising the third dielectric liner material 412. Different portions of an individual word line structure 414 may form gates for multiple vertical channel access devices 218.

The first x-axis trenches 402, including the recesses 416 between the word line structures 414 within the first x-axis trenches 119, may be filled with a first insulative material 418. The first x-axis trenches 402 may be filled with the first insulative material 418 up to upper vertical boundaries of the first doped regions 114 of the semiconductor projections 110. The first insulative material 418 may be a spin-on dielectric material, and may be formed by a spin coating process. Moreover, the first insulative material 418 may include any of the dielectric materials described herein. The first insulative material 418 may optionally be subjected to an annealing process.

Referring still to FIG. 4, remaining portions (e.g., top portions) of the first x-axis trenches 402 (e.g., spaces between neighboring second patterned masking lines 406) and over the first insulative material 418 may be filled with a third mask material 420. The third mask material 420 may be formed and deposited within the remaining portions (e.g., top portions) of the first x-axis trenches 402 via any of the deposition manners described herein. The third mask material 420 may be formed of and include a dielectric material, such as a low-k dielectric material (e.g., silicon oxycarbide).

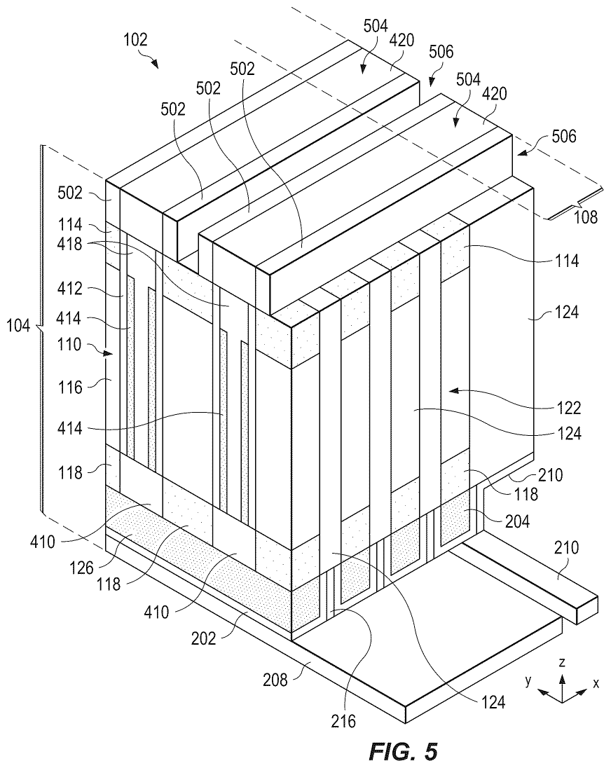

Referring to FIG. 5, the second mask material 404 may be removed (e.g., recessed through an etching process (dry or wet etching process)), and spacer materials 502 may be formed on exposed vertical sidewalls of the third mask material 420. In some embodiments, the spacer materials 502 are formed by filling spaces (e.g., voids) between neighboring portions of the third mask material 420 and over the first insulative material 418 created by removal of the second mask material 404 with a spacer material and then removing center portions of the spacer material through one or more etching processes. In other embodiments, the spacer materials 502 are formed by depositing a spacer material as a liner over at least exposed sidewalls of the third mask material 420 and removing any undesired portions of the spacer material through one or more etching processes. The spacer materials 502 may be formed of and include a dielectric material, such as a low-k dielectric material (e.g., silicon oxycarbide).

Together, the third mask material 420 and the spacer materials 502 may form third patterned masking lines 504 horizontally extending in parallel with one another in the X-direction. Openings 506 may be defined between neighboring third patterned masking lines 504 and expose upper surfaces of the first doped regions 114 and the first isolation material 124.

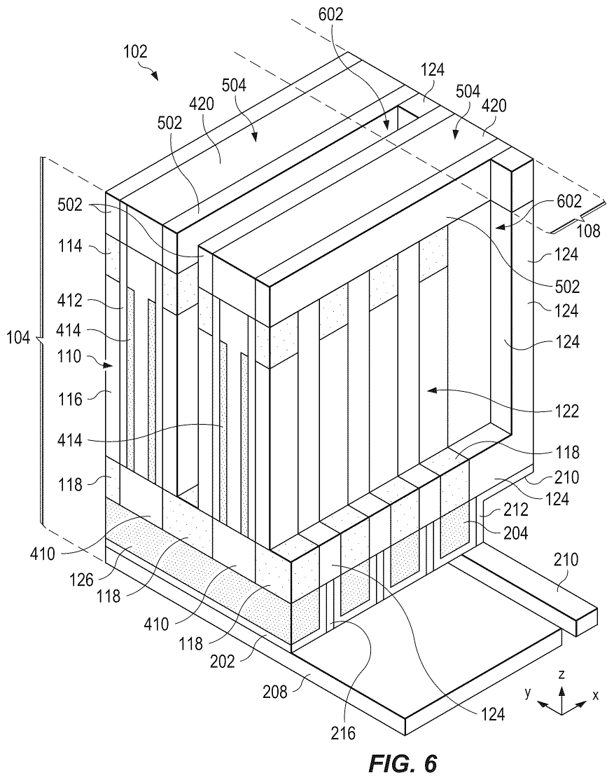

Referring to FIG. 6, in some embodiments, additional first isolation material 124 or another isolation material is deposited within the openings 506 at least within the edge of array region 108 of the microelectronic device such that upper surfaces of the first isolation material 124 within the edge of array region 108 are at least substantially coplanar with upper surfaces of the third patterned masking lines 504. Additionally, the third patterned masking lines 504 and the openings 506 may be employed to form second x-axis trenches 602 extending vertically into the first assembly 104. The second x-axis trenches 602 may extend horizontally in parallel in the X-direction. The second x-axis trenches 602 may extend vertically into the first assembly 104 to an elevation (e.g., vertical level) at least substantially coplanar with upper surfaces of the second doped regions 118 of the semiconductor projections 110. Accordingly, lower boundaries (e.g., bottoms) of the second x-axis trenches 602 may be defined by exposed upper surfaces of the second doped regions 118 of the semiconductor projections 110 and the first isolation material 124.

The second x-axis trenches 602 may terminate in the X-direction within or at the edge of array region 108 of the microelectronic device. One or more additional mask materials may be utilized during formation of the second x-axis trenches 602 to form horizontal boundaries of the second x-axis trenches 602 in the X-direction at or within the edge of array region 108 of the microelectronic device. In particular, a horizontal boundary of each of the second x-axis trenches 602 in the X-direction may horizontally overlap with the edge of array region 108 or be at least substantially coplanar with a horizontal boundary of the edge of array region 108. As a result, a horizontal boundary of each of the second x-axis trenches 602 in the X-direction may defined by vertical sidewalls of remaining portions of the first isolation material 124 within the edge of array region 108 of the microelectronic device. Accordingly, a horizontal boundary of each of the second x-axis trenches 602 may be directly vertically above the back gate plate 210.

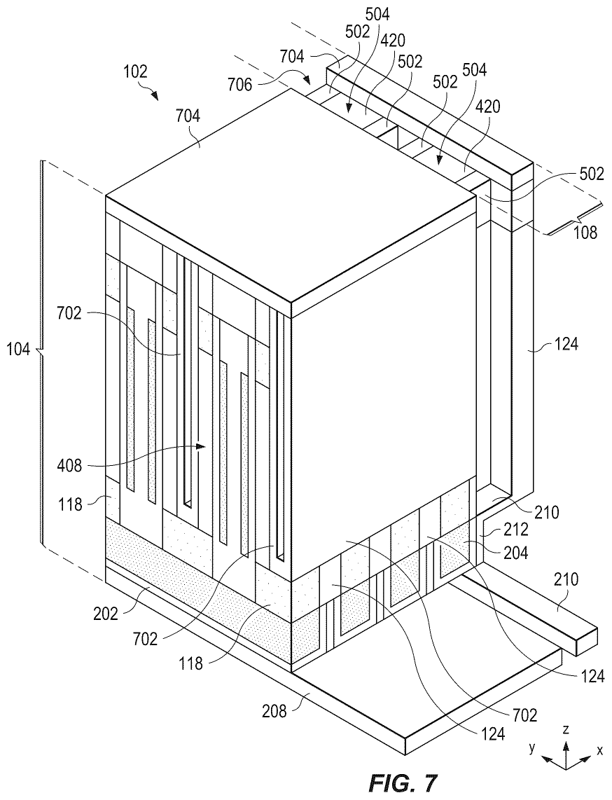

Referring to FIG. 7, a fourth dielectric liner material 702 (i.e., a gate dielectric material) may be formed in the second x-axis trenches 602. In some embodiments, the fourth dielectric liner material 702 is formed (e.g., conformally deposited) inside second x-axis trenches 602. In particular, the fourth dielectric liner material 702 may be formed over an along vertical sidewalls of the spacer materials 502, over exposed vertical sidewalls of the semiconductor projections 110 (i.e., semiconductor pillars 408), over exposed upper surfaces of the first isolation material 124, and over exposed upper surfaces of the second doped regions 118 of the semiconductor projections 110. The fourth dielectric liner material 702 may also be referred to as a gate dielectric material.

The fourth dielectric liner material 702 (i.e., gate dielectric material) may be formed of and include insulative material. In some embodiments, the fourth dielectric liner material 702 is formed of and includes silicon dioxide. In one or more embodiments, the fourth dielectric liner material 702 includes a material with a relatively high dielectric constant (k) (i.e., a high-k material). The fourth dielectric liner material 702 may have a thickness within a range of from about 4 nm to about 6 nm (e.g., about 5 nm).

Additionally, a fourth mask material 704 (e.g., a slot mask material) may be formed over exposed upper surfaces of the third mask material 420, the spacer material 502, the first isolation material 124, and the fourth dielectric liner material 702 (i.e., a current upper surface of the first assembly 104), and the fourth mask material 704 may be patterned to form a contact slot opening 706 horizontally extending in the Y-direction and extending vertically through the fourth mask material 704. The contact slot opening 706 may horizontally overlap with the back gate plate 210. Moreover, a first horizontal boundary of the contact slot opening 706 in the X-direction may horizontally overlap with the edge of array region 108 or be at least substantially coplanar with a horizontal boundary of the edge of array region 108. In one or more embodiments, the first horizontal boundary of the contact slot opening 706 is offset from the horizontal boundary of the edge of array region 108 of the microelectronic device in the X-direction. For example, the first horizontal boundary of the contact slot opening 706 may be entirely within the edge of array region 108 of the microelectronic device. In some embodiments, the first horizontal boundary of the contact slot opening 706 is at least substantially coplanar with vertical sidewall surfaces of the first isolation material 124 within the edge of array region 108. A second, opposite horizontal boundary of the contact slot opening 706 in the X-direction may horizontally overlap with the second dielectric liner material 202 lining a vertical sidewall of the outermost digit line structure 204. For instance, the second, opposite horizontal boundary of the contact slot opening 706 may be at least substantially coplanar with a vertical sidewall surface of the conductive material 212 of the back gate plate 210 contacting the second dielectric liner material 202 lining a vertical sidewall of the outermost digit line structure 204.

The fourth mask material 704 may be patterned to define the contact slot opening 706 utilizing any suitable methodology. For instance, in some embodiments, a photoresist material is formed on or over the fourth mask material 704, is patterned (e.g., photo exposed and developed), and then an opening formed in the patterned photoresist material is extended into the fourth mask material 704 to form the contact slot opening 706. The fourth mask material 704 may be removed during subsequent processing stages, or may remain in a final device formed through the methods of the disclosure. The fourth mask material 704 may be formed of and include a dielectric material, such as a dielectric nitride material (e.g., silicide nitride).

The fourth mask material 704 and the contact slot opening 706 may be employed to remove the fourth dielectric liner material 702 and the first isolation material 124 horizontally overlapping with the contact slot opening 706. Put another way, the fourth mask material 704 and the contact slot opening 706 may be employed to remove the fourth dielectric liner material 702 and the first isolation material 124 directly vertically below the contact slot opening 706 defined by the fourth mask material 704. One or more portions of the fourth dielectric liner material 702 and the first isolation material 124 overlying the back gate plate 210 within the edge of array region 108 of the microelectronic device may be removed by way of this removal process. In some embodiments, the removal process includes an etching process (e.g., an anisotropic etching process) that selectively removes exposed portions of the fourth dielectric liner material 702 and the first isolation material 124 relative to the remaining portions of the fourth mask material 704 defining the contact slot opening 706 without removing portions of the third mask material 420, the spacer material 502, or the conductive material 212 forming the back gate plate 210. Accordingly, upper surfaces of the back gate plate 210 may be exposed by way of the etching process.

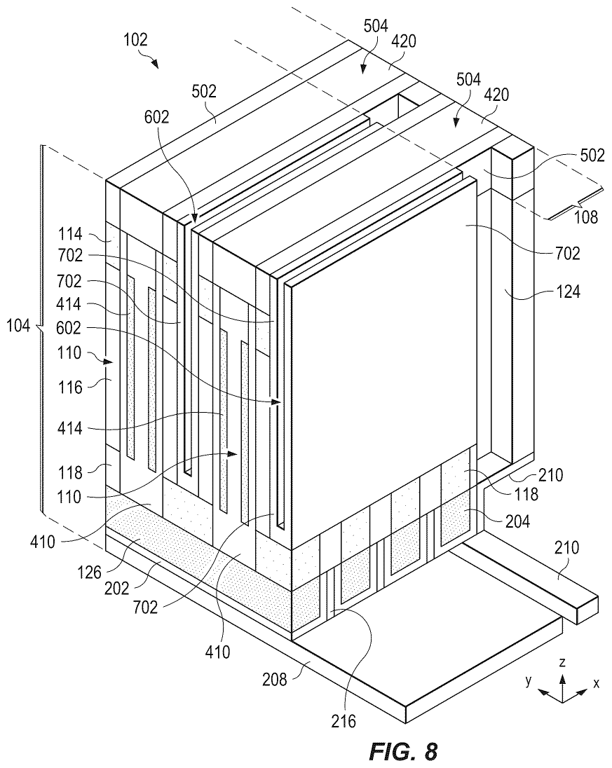

Referring to FIG. 7 and FIG. 8 together, the fourth mask material 704 above upper vertical boundaries of the third patterned masking lines 504 (i.e., the third mask material 420 and the spacer material 502) and the fourth dielectric liner material 702 lining the second x-axis trenches 602 may be removed. For example, the fourth mask material 704 above upper vertical boundaries of the third patterned masking lines 504 (i.e., the third mask material 420 and the spacer material 502) and the fourth dielectric liner material 702 lining the second x-axis trenches 602 may be removed by way of a CMP process. Due to the removal of the fourth mask material 704, portions of the third patterned masking lines 504 (i.e., the third mask material 420 and the spacer material 502), the fourth dielectric liner material 702 lining the second x-axis trenches 602, and the first isolation material 124 are exposed on a current upper surface of the first assembly 104.

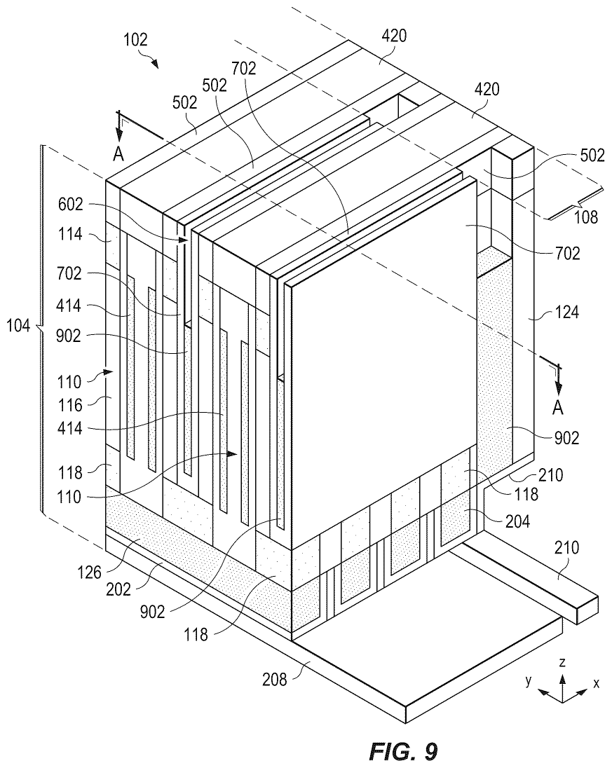

Referring to FIG. 4 and FIG. 9 together, at least some of the first x-axis trenches 402 have larger widths, in the Y-direction, than the second x-axis trenches 602. Furthermore, in some embodiments, each of the first x-axis trenches 402 is formed in between two neighboring second x-axis trenches 602.

Back gate structures 902 may be formed on the fourth dielectric liner material 702 and within the second x-axis trenches 602. The back gate structure 902 may include any of the conductive materials described herein. In one or more embodiments, the back gate structures 902 are formed by at least partially filling the second x-axis trenches 602 with a gate electrode material, and subsequently removing one or more portions of the gate electrode material. As non-limiting examples, within the second x-axis trenches 602, subsequent to depositing the gate electrode material within the second x-axis trenches 602, an entirety of the gate electrode material may be recessed down to a desired upper boundary of the back gate structures 902, and the remaining gate electrode material within each second x-axis trench 602 forms a given back gate structure 902.

The gate electrode material may be formed (e.g., deposited) through any of the manners described herein. Additionally, recessing the gate electrode material and forming the recesses in the gate electrode material may be done by conventional techniques, such as by a directional, selective etch process (e.g., an anisotropic etch process, such as an anisotropic dry or wet etch process) that removes the gate electrode material without significantly removing other exposed materials (e.g., the fourth dielectric liner material 702) of the first assembly 104.

Any unfilled portions of the second x-axis trenches 602 above the back gate structures 902 may be filled with a second insulative material. The second x-axis trenches 602 may be filled with the second insulative material up to upper vertical boundaries of the fourth dielectric liner material 702 and the third patterned masking lines 504. The second insulative material may be a spin-on dielectric material, and may be formed by a spin coating process. Moreover, the second insulative material may include any of the dielectric materials described herein. The second insulative material may optionally be subjected to an annealing process.

Referring still to FIG. 9, the back gate structures 902 may be vertically spaced from the second doped regions 118 of the semiconductor projections 110 by the fourth dielectric liner material 702. Furthermore, the back gate structures 902 may be formed over the exposed portions of the back gate plates 210 within the edge of array region 108 of the microelectronic device. In particular, the back gate structures 902 may be coupled to (e.g., in physical contact with, electrical contact with) the back gate plates 210 within the edge of array region 108 of the microelectronic device. In some embodiments, a portion of a given back gate structure 902 in contact with the back gate plate 210 is thicker in the Y-direction than a remainder of the given back gate structure 902 at least partially due to the removal of the fourth dielectric liner material 702 during the processes described above in regard to FIG. 8. Accordingly, the back gate structures 902 may have varying thicknesses along the longitudinal lengths of the back gate structures 902 in the X-direction. Furthermore, each of the back gate structures 902 of the memory array structure 102 may be coupled to a common back gate plate 210 within the edge of array region 108. The back gate structures 902 may also vertically overlap with second doped regions 118 of semiconductor projections 110 of the vertical channel access devices 218, and as noted above, each second doped region 118 of the semiconductor projections 110 may be direct contact with a respective digit line structure 126 of the digit line structures 126.

The back gate structures 902 and back gate plate 210 provide advantages over conventional memory array structures and microelectronic devices. In particular, formation of the back gate plate 210 and coupling the back gate structures 902 directly to the back gate plate 210 within the edge of array region 108 enables the formation of buried contacts to the back gate structures 902 and avoids a need of forming individual relatively tight connections (e.g., contacts) to each back gate structure 902 in later processes, which is typically required in conventional memory array structures. Furthermore, formation of the back gate plate 210 and coupling the back gate structures 902 directly to the back gate plate 210 within the edge of array region 108 enables connections between the back gate structures 902 and the back gate plate 210, and as a result, operable connections to voltage supplies at the edge of array region 108 of the microelectronic device without impacting socket size within word line exit regions of the microelectronic device and without a need to contact each back gate structure 902 individually, as each of the back gate structures 902 within the given memory array structure 102 are connected to the back gate plate 210.

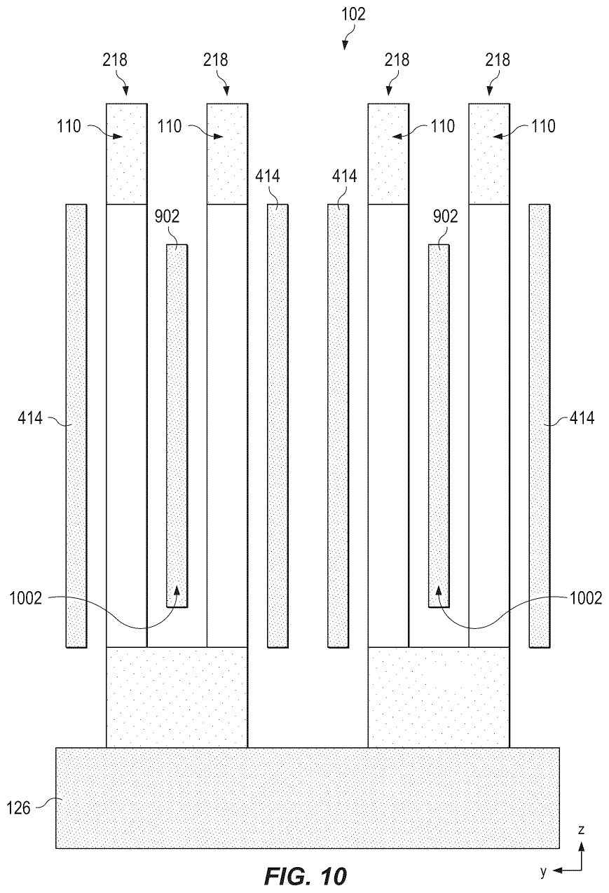

FIG. 10 is a simplified, vertical cross-sectional view of the memory array structure 102 along the line A-A of FIG. 9. Referring to FIG. 9 and FIG. 10 together, the back gate structures 902 within the second x-axis trenches 602 may form shield gates 1002 that shield word line structures 414 from cross-interference between word line structures 414. For example, the shield gates 1002 may control electrical field interference between vertical channel access devices 218 (e.g., vertical transistors, access transistors) that include the semiconductor projections 110. In some embodiments, the shield gates 1002 are formed from tungsten or another conductive material. In one or more embodiments, the shield gates 1002 are formed from a semiconductor material (e.g., polysilicon). Furthermore, as described above, the shield gates 1002 may be operably connected to a respective voltage supply at the edge of array region 108 by way of the back gate plates 210.

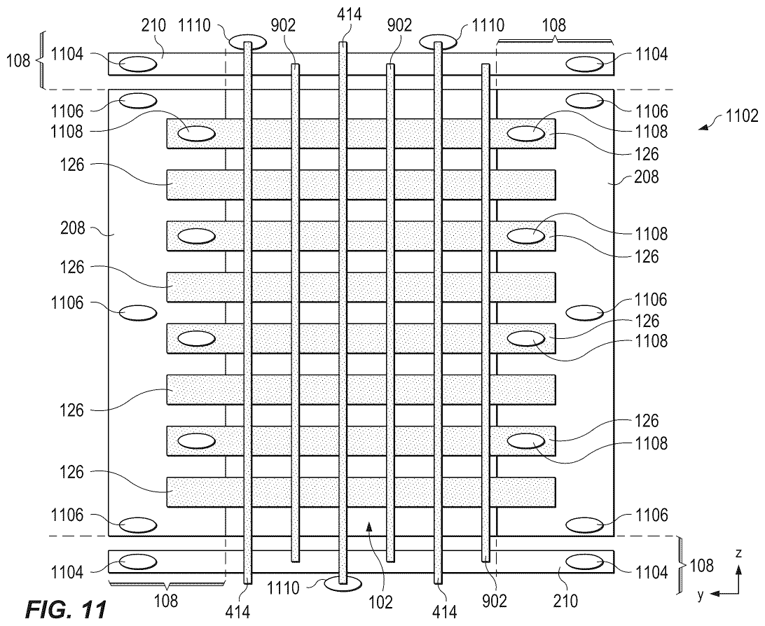

As shown in FIGS. 9 and 10, the back gate structures 902 may be horizontally interposed between neighboring vertical channel access devices 218 in the Y-direction, which is orthogonal to the X-direction, and may extend in the X-direction. During use and operation of a microelectronic device of the disclosure (e.g., as described in further detail below with reference to FIG. 11), the back gate structures 902 may be employed to tune electrical properties of the vertical channel access devices 218. For example, the back gate structures 902 may be employed to modify threshold voltages of the vertical channel access devices 218 and/or to reduce leakage current (enhancing control over the vertical channels of the vertical channel access devices 218).

FIG. 11 is a simplified, schematic, top cross-sectional view of a microelectronic device 1102 including at least one first assembly 104 including a memory array structure 102 oriented over a shield structure 208. Not every element of the first assembly 104 is depicted within FIG. 11 for clarity and ease of depiction, and the first assembly 104 may include any of the materials, structures, and elements (e.g., dielectric materials, dielectric liner materials, structures, etc.) of the first assemblies 104 described above in regard to FIG. 1 through FIG. 10.

As is shown in FIG. 11, and as described above, the first assembly 104 may include the shield structure 208, back gate plates 210 on opposing sides of the shield structure 208 in the X-direction, word line structures 414 extending in the X-direction and through the memory array structure 102, back gate structures 902 extending in the X-direction and through the memory array structure 102, and digit line structures 126 extending in the Y-direction and through the memory array structure 102. Furthermore, edge of array regions 108 may be defined on opposing sides of the memory array structure 102 (e.g., at or proximate horizontal edges of a patch region of the microelectronic device 1102) in both the X-direction and the Y-direction.

As described above, the back gate structures 902 may be operably coupled to the back gate plates 210. Additionally, back gate plate contacts 1104 of the first assembly 104 may be formed and located within the edge of array regions 108 of the microelectronic device 1102 and may be coupled to the back gate plates 210. In some embodiments, the back gate plate contacts 1104 are horizontally offset from the back gate structures 902 in Y-direction. Moreover, the back gate plate contacts 1104 may contact the back gate plate 210 from a side of the back gate plate 210 opposite the back gate structures 902 and within the edge of array region 108. Furthermore, as described above, the back gate structures 902 (e.g., shield gates 1002) may be operably connected to a respective voltage supply at the edge of array region 108 by way of the back gate plates 210 and the back gate plate contacts 1104. The voltage supply may be utilized to control or enhance protection provided by back gate structures 902 (e.g., shield gates 1002) from undesirable electrical interference (e.g., electromagnetic interference (EMI)) between word line structures 414.

Furthermore, shield contacts 1106 of the shield structure 208 of the first assembly 104 may be formed and located at or proximate horizontal edges of the first assembly 104 and within edge of array regions 108. In other words, the shield contacts 1106 of the shield structures 208 may be formed proximate horizontal perimeters of the first assembly 104. As noted above, the shield contacts 1106 may be utilized to bias the shield structure 208 with a voltage to control or enhance protection provided by the shield structure 208 from undesirable electrical interference (e.g., electromagnetic interference (EMI)). In some embodiments, the shield contacts 1106 of the first assembly 104 are formed within edge of array regions 108 proximate digit line exit regions of the first assembly 104. In other embodiments, the shield contacts 1106 of the first assembly 104 are formed within edge of array regions 108 opposite digit line exit regions of the first assembly 104.

Digit line contacts 1108 of the first assembly 104 may be formed and located at or proximate horizontal edges of the first assembly 104, within edge of array regions 108, and within digit line contact socket regions of the first assembly 104. In other words, the digit line contacts 1108 may be formed proximate horizontal perimeters of the first assembly 104. The digit line contacts 1108 may be formed to contact (e.g., physically contact, electrically contact) respective digit line structures 126 and to couple the digit line structures 126 to other circuitry (e.g., sense amplifiers (e.g., equalization (EQ) amplifiers, isolation (ISO) amplifiers, NMOS sense amplifiers (NSAs), PMOS sense amplifiers (PSAs)), read buffers, decoders (e.g., local deck decoders, column decoders, row decoders), pre-charge circuits, and drivers (e.g., main digit line drivers, sub digit line drivers)) of the microelectronic device 1102.

Word line contacts 1110 of the first assembly 104 may be formed and located at or proximate horizontal edges of the first assembly 104, within edge of array regions 108, and within word line contact socket regions of the first assembly 104. In other words, the word line contacts 1110 may be formed proximate horizontal perimeters of the first assembly 104. The word line structures 414 may extend from the memory array structure 102 and beyond the back gate plate 210 in the X-direction. Accordingly, the word line contacts 1110 may be horizontally offset from the back gate plate 210 and the back gate plate contacts 1104 in the X-direction. The word line contacts 1110 may be formed to contact (e.g., physically contact, electrically contact) respective word line structures 414 and to couple the word line structures 414 to other circuitry (e.g., charge pumps (e.g., V_{CCP} charge pumps, V_{NEGWL} charge pumps, DVC2 charge pumps), drivers (e.g., main word line drivers, sub word line drivers (SWD)), decoders (e.g., local deck decoders, column decoders, row decoders), repair circuitry (e.g., column repair circuitry, row repair circuitry), and memory test devices) of the microelectronic device 1102. In some embodiments, the word line contacts 1110 are part of contact assemblies coupled to a cell plate and connecting various structures vertically throughout the microelectronic device 1102.

An accordance with some embodiments of the disclosure a microelectronic device may include a memory array structure comprising: an array region comprising vertical channel access devices of memory cells within a horizontal area thereof, the access devices comprising word line structures extending in a first horizontal direction; and back gate structures horizontally interposed between neighboring vertical channel access devices in a second horizontal direction, orthogonal to the first horizontal direction, and extending in the first horizontal direction; an edge of array region horizontally neighboring the memory array structure in the first horizontal direction; digit line structures vertically overlying the vertical channel access devices of the memory cells; a shield structure vertically overlying the digit line structures of the memory cells of the memory array structure; and a back gate plate formed within the edge of array region, in contact with the back gate structures of the memory array structure, and at least partially vertically overlapping with the digit line structures.

Thus, in accordance with embodiments of the disclosure, a method of forming a microelectronic device may include forming a memory array structure comprising forming an array channel region having volatile memory cells within a horizontal area of the array region, the volatile memory cells respectively comprising a vertical channel access device; and forming back gate structures horizontally interposed between neighboring vertical channel access devices and extending in a first horizontal direction; forming digit line structures vertically overlying the vertical channel access devices of the volatile memory cells; and forming a back gate plate within an edge of array region of the microelectronic device to contact the back gate structures of the memory array structure and at least partially vertically overlap with the digit line structure.

Moreover, in accordance with some embodiments of the disclosure, a microelectronic device may include a memory array structure comprising: an array region comprising vertical channel access devices of memory cells within a horizontal area thereof; and back gate structures extending through the array region and between neighboring vertical channel access devices; digit line structures vertically overlying the vertical channel access devices of the memory cells; an edge of array region proximate a horizontal boundary of the memory array structure; and a back gate plate formed within the edge of array region, in contact with the back gate structures of the memory array structure, and at least partially vertically overlapping with the digit line structures.

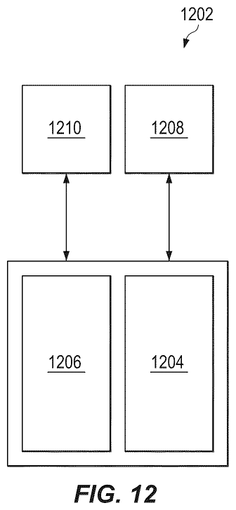

Microelectronic devices (e.g., the microelectronic device 1102 (FIG. 11)) in accordance with embodiments of the disclosure may be used in embodiments of electronic systems of the disclosure. For example, FIG. 12 is a block diagram illustrating an electronic system 1202 according to embodiments of disclosure. The electronic system 1202 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1202 includes at least one memory device 1204. The memory device 1204 may comprise, for example, a microelectronic device (e.g., the microelectronic device 1102 (FIG. 11)) previously described herein. The electronic system 1202 may further include at least one electronic signal processor device 1206 (often referred to as a “microprocessor”). The electronic signal processor device 1206 may, optionally, comprise a microelectronic device (e.g., the microelectronic device 1102 (FIG. 11)) previously described herein. While the memory device 1204 and the electronic signal processor device 1206 are depicted as two (2) separate devices in FIG. 12, in additional embodiments, a single (e.g., only one) memory/processor device having the functionalities of the memory device 1204 and the electronic signal processor device 1206 is included in the electronic system 1202. In such embodiments, the memory/processor device may include a microelectronic device (e.g., the microelectronic device 1102 (FIG. 11)) previously described herein. The electronic system 1202 may further include one or more input devices 1208 for inputting information into the electronic system 1202 by a user, such as, for example, a mouse or other pointing device, a keyboard, a touchpad, a button, or a control panel. The electronic system 1202 may further include one or more output devices 1210 for outputting information (e.g., visual or audio output) to a user such as, for example, a monitor, a display, a printer, an audio output jack, a speaker, etc. In some embodiments, the input device 1208 and the output device 1210 comprise a single touchscreen device that can be used both to input information to the electronic system 1202 and to output visual information to a user. The input device 1208 and the output device 1210 may communicate electrically with one or more of the memory device 1204 and the electronic signal processor device 1206.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. Any equivalent embodiments are within the scope of this disclosure. For example, elements and features disclosed in relation to one embodiment may be combined with elements and features disclosed in relation to other embodiments of the disclosure. Various modifications of the disclosure, in addition to those shown and described herein, such as alternate useful combinations of the elements and features described, will become apparent to those skilled in the art from the description. Such modifications and embodiments also fall within the scope of the appended claims and equivalents.

What is claimed is:

1. A microelectronic device, comprising:
a memory array structure comprising:
an array region comprising vertical channel access devices of memory cells within a horizontal area thereof, the access devices comprising word line structures extending in a first horizontal direction; and
back gate structures horizontally interposed between neighboring vertical channel access devices in a second horizontal direction, orthogonal to the first horizontal direction, and extending in the first horizontal direction;
an edge of array region horizontally neighboring the memory array structure in the first horizontal direction;
digit line structures vertically overlying the vertical channel access devices of the memory cells;
a shield structure vertically overlying the digit line structures of the memory cells of the memory array structure; and
a back gate plate formed within the edge of array region, in contact with the back gate structures of the memory array structure, and at least partially vertically overlapping with the digit line structures.

2. The microelectronic device of claim 1, wherein a lowermost surface of the back gate plate is at least substantially coplanar with lowermost surfaces of the digit line structures.

3. The microelectronic device of claim 1, wherein the back gate plate is in contact with multiple back gate structures of the back gate structures.

4. The microelectronic device of claim 1, wherein the back gate plate lines a vertical surface of a dielectric liner material lining a digit line structure of the digit line structures most proximate the edge of array region of the microelectronic device.

5. The microelectronic device of claim 1, further comprising at least one back gate plate contact contacting the back gate plate on a side of the back gate plate opposite the back gate structures and within the edge of array region of the microelectronic device.

6. The microelectronic device of claim 5, wherein the back gate plate contact is operably coupled to at least one voltage supply.

7. The microelectronic device of claim 1, further comprising a dielectric liner material formed between the back gate structures and semiconductor projections of the vertical channel access devices of the memory cells.

8. The microelectronic device of claim 1, wherein the back gate structures vertically overlap with doped regions of semiconductor projections of the vertical channel access devices, and wherein each doped region of the semiconductor projections is in direct contact with a respective digit line structure of the digit line structures.

9. The microelectronic device of claim 1, wherein each of the back gate structures comprises a varying thickness along its length in the first horizontal direction.

10. The microelectronic device of claim 1, wherein the shield structure comprises projections that extend vertically between pairs of the digit line structures horizontally neighboring one another.

11. The microelectronic device of claim 1, wherein the shield structure is coupled to a shield contact proximate a horizontal boundary of the memory array structure.

12. A method of forming a microelectronic device, comprising:
forming a memory array structure comprising:
forming an array channel region having volatile memory cells within a horizontal area of the array channel region, the volatile memory cells respectively comprising a vertical channel access device; and
forming back gate structures horizontally interposed between neighboring vertical channel access devices and extending in a first horizontal direction;
forming digit line structures vertically overlying the vertical channel access devices of the volatile memory cells; and
forming a back gate plate within an edge of array region of the microelectronic device to contact the back gate structures of the memory array structure and at least partially vertically overlap with the digit line structures.

13. The method of claim 12, wherein forming the back gate plate comprises forming a lowermost surface of the back gate plate to be at least substantially coplanar with lowermost surfaces of the digit line structures.

14. The method of claim 12, wherein forming the back gate structures comprising operably coupling multiple gate structures to the back gate plate.

15. The method of claim 12, wherein forming the back gate plate comprises forming the back gate plate to line a vertical surface of a dielectric liner material lining a digit line structure of the digit line structures most proximate the edge of array region of the microelectronic device.

16. The method of claim 12, further comprising forming at least one back gate plate contact contacting the back gate plate on a side of the back gate plate opposite the back gate structures and within the edge of array region of the microelectronic device.

17. The method of claim 16, further comprising operably coupling the back gate plate contact to at least one voltage supply.

18. The method of claim 12, wherein forming the back gate structures comprises forming the back gate structures to vertically overlap with doped regions of semiconductor projections of the vertical channel access devices, and wherein each doped region of the semiconductor projections is in direct contact with a respective digit line structure of the digit line structures.

19. The method of claim 12, wherein forming the back gate structures comprises forming a portion each back gate structure that is contacting the back gate plate to have a greater thickness in a second horizontal direction, orthogonal to the first horizontal direction, than a remainder of the back gate structure.

20. A microelectronic device, comprising:
a memory array structure comprising:
an array region comprising vertical channel access devices of memory cells within a horizontal area thereof; and
back gate structures extending through the array region and between neighboring vertical channel access devices;
digit line structures vertically overlying the vertical channel access devices of the memory cells;
an edge of array region proximate a horizontal boundary of the memory array structure; and
a back gate plate formed within the edge of array region, in contact with the back gate structures of the memory array structure, and at least partially vertically overlapping with the digit line structures.
